(19) United States
(12) Patent Application Publication
(10) Pub. No.: US 2025/0219013 A1
(43) Pub. Date: Jul. 3, 2025

(54) BONDING APPARATUS, CHUCK EXCHANGE APPARATUS, AND ARTICLE MANUFACTURING METHOD

(71) Applicant: CANON KABUSHIKI KAISHA, Tokyo (JP)

(72) Inventors: KAI TAKAHASHI, Tochigi (JP); Yusuke Kubota, Shiga (JP)

(21) Appl. No.: 18/985,806

(22) Filed: Dec. 18, 2024

(30) Foreign Application Priority Data
Dec. 27, 2023 (JP) 2023-221462

(51) Int. Cl. H01L 23/00

(52) U.S. Cl. CPC H01L 24/75; H01L 24/74; H01L 2224/74; H01L 2224/75734; H01L 2224/75744; H01L 2924/40

(57) ABSTRACT

The present invention provides a bonding apparatus that performs a process of bonding a first member to a second member, comprising: a first holder configured to hold a chuck to be brought into contact with the first member in the process; a second holder configured to hold the chuck in attachment of the chuck to the first holder and/or detachment of the chuck from the first holder; a first attraction force generating mechanism configured to generate a first attraction force between the first holder and the chuck; a second attraction force generating mechanism configured to generate a second attraction force between the second holder and the chuck; and a controller configured to adjust at least one of the first attraction force and the second attraction force.

### BACKGROUND OF THE INVENTION

### Field of the Invention

The present invention relates to a bonding apparatus, a chuck exchange apparatus, and an article manufacturing method.

### Description of the Related Art

As a semiconductor manufacturing apparatus for manufacturing a semiconductor device or the like, a bonding apparatus that bonds a die as a bonded object onto a substrate as a bonding target object is known. For example, in the bonding apparatus, a step of picking up one die from a plurality of dies arranged on a dicing tape, a step of conveying the picked-up die, and a step of bonding the conveyed die onto a substrate are performed. A jig to be brought into contact with the die is provided in the distal end of a head that holds the die in these steps. This jig is sometimes called a collet chuck, and may simply be referred to as a collet hereinafter.

The collet is detachably provided in the head, and may be exchanged in accordance with the type (for example, size) of the die or due to damage or contamination of the collet. Therefore, the bonding apparatus can be provided with a mechanism for attaching and detaching the collet to and from the head. Japanese Patent Laid-Open No. 2018-206843 discloses a technique of attaching/detaching the collet to/from the head (collet holder) while gripping the collet with an opening/closing arm including a claw structure.

With the technique described in Japanese Patent Laid-Open No. 2018-206843, since the opening/closing arm slides with the collet upon gripping the collet with the opening/closing arm including the claw structure, particles can be generated every time the collet is attached/detached. If these particles attach to the collet, the die may be tilted and held by the collet due to the particles, and this makes it difficult to bond the die onto a substrate with high accuracy. Hence, a technique of reducing generation of particles in attachment and detachment of the collet is desired.

### SUMMARY OF THE INVENTION

The present invention provides, for example, a technique advantageous in reducing generation of particles in a bonding apparatus.

According to one aspect of the present invention, there is provided a bonding apparatus that performs a process of bonding a first member to a second member, comprising: a first holder configured to hold a chuck to be brought into contact with the first member in the process; a second holder configured to hold the chuck in attachment of the chuck to the first holder and/or detachment of the chuck from the first holder; a first attraction force generating mechanism configured to generate a first attraction force between the first holder and the chuck; a second attraction force generating mechanism configured to generate a second attraction force between the second holder and the chuck; and a controller configured to adjust at least one of the first attraction force and the second attraction force.

Further features of the present invention will become apparent from the following description of exemplary embodiments with reference to the attached drawings.

### BRIEF DESCRIPTION OF THE DRAWINGS

FIG. 1 is a view showing an arrangement example of a bonding apparatus;

FIGS. 2A and 2B are views showing an arrangement example of a pickup head;

FIG. 3 is a view showing an arrangement example of a collet exchange unit;

FIGS. 4A to 4G are views showing representative examples of the specific arrangement of each of a collet, a collet holder, and an exchange holder;

FIGS. 5A to 5C are views showing a specific example of a detachment process;

FIG. 6 is a flowchart illustrating the detachment process;

FIG. 7 is a flowchart illustrating an attachment process;

FIGS. 8A and 8B are views each showing an arrangement example of the collet, the collet holder, and the exchange holder of Example 1;

FIGS. 9A and 9B are views each showing an arrangement example of the collet, the collet holder, and the exchange holder of Example 2;

FIGS. 10A and 10B are views each showing an arrangement example of the collet, the collet holder, and the exchange holder of Example 3;

FIGS. 11A and 11B are views each showing an arrangement example of the collet, the collet holder, and the exchange holder of Example 4;

FIGS. 12A and 12B are views each showing an arrangement example of the collet, the collet holder, and the exchange holder of Example 5;

FIGS. 13A and 13B are views each showing an arrangement example of the collet, the collet holder, and the exchange holder of Example 6;

FIG. 14 is a view showing an arrangement example of the collet, the collet holder, and the exchange holder of Modification 1; and

FIG. 15 is a view showing an arrangement example of the collet, the collet holder, and the exchange holder of Modification 2.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

In the specification and the accompanying drawings, directions will be typically indicated on an XYZ coordinate system in which a surface parallel to a horizontal surface is defined as the X-Y plane. Directions parallel to the X-axis, the Y-axis, and the Z-axis of the XYZ coordinate system are defined as the X direction, the Y direction, and the Z direction, respectively. A rotation about the X-axis, a rotation about the Y-axis, and a rotation about the Z-axis are defined as θX, θY, and θZ, respectively. Control and driving (movement) concerning the X-axis, the Y-axis, and the Z-axis mean control or driving (movement) concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively.

### First Embodiment

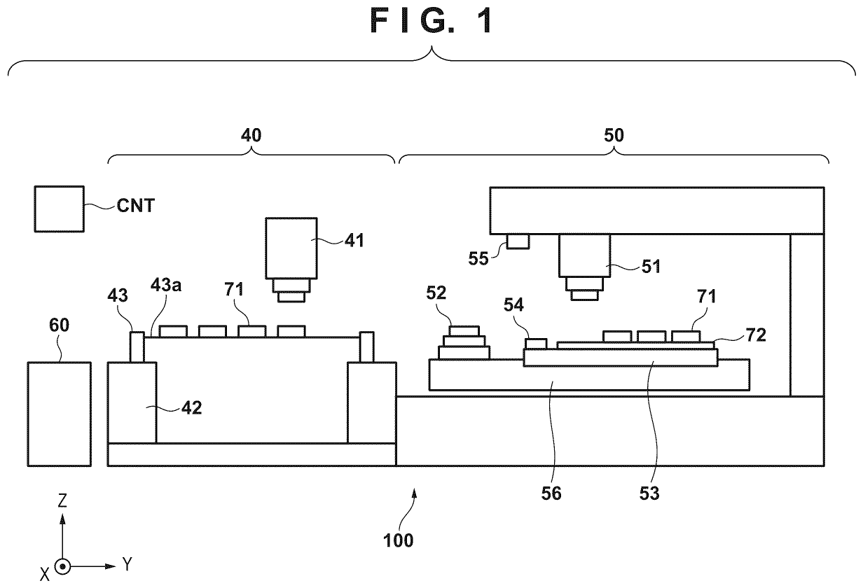

A bonding apparatus 100 of the first embodiment according to the present invention will be described. FIG. 1 is a schematic view showing an arrangement example of the bonding apparatus 100 of this embodiment. The bonding apparatus 100 is an apparatus that bonds the first member (bonded object) to the second member (bonding target object), and can be used as a semiconductor manufacturing apparatus for manufacturing a semiconductor device. The bonding apparatus 100 of this embodiment is an apparatus that sequentially bonds each of a plurality of the first members to the second member. Note that the arrangement example of the bonding apparatus 100 shown in FIG. 1 and the procedure of a bonding process to be described below are merely examples and do not intend to limit the form of the present invention.

As the first member, for example, a chip having a bonding surface on which a pattern is provided can be used. Examples of the chip are a stack of dies, a small piece of a material, an optical element, a MEMS, and a structure, in addition to a die obtained by dividing into pieces a wafer on which semiconductor devices are formed. In this embodiment, an example of using a die as the first member will be described. The first member will sometimes be referred to as the “die” hereinafter.

As the second member, for example, a substrate having a bonding target surface on which a pattern is provided can be used. Examples of the substrate are a silicon wafer, a silicon wafer on which wirings are formed, a glass wafer, a glass panel on which wirings are formed, an organic panel (PCB) on which wirings are formed, and a metal panel, in addition to a wafer on which semiconductor devices are formed. The substrate may be a wafer to which one or more dies are already bonded. In this embodiment, an example of using a wafer as the second member will be described. The second member will sometimes be referred to as the “substrate” hereinafter.

In this embodiments, various temporary or permanent bonding methods can be applied as a bonding method for the first member (die) and the second member (substrate). Examples of the bonding method are bonding using an adhesive, temporary bonding using a temporary adhesive, bonding by hybrid bonding, atomic diffusion bonding, vacuum bonding, and bump bonding.

As shown in FIG. 1, the bonding apparatus 100 includes a pickup unit 40, a bonding unit 50, and a controller CNT. The controller CNT is formed from, for example, a computer (information processing apparatus) including a processor such as a Central Processing Unit (CPU) and a storage such as a memory. The controller CNT controls the bonding process by controlling each unit of the bonding apparatus 100. The bonding process can include a step of picking up a die 71 (first member) by the pickup unit 40, and a step of bonding the die 71 onto a substrate 72 by the bonding unit 50. The controller CNT can also control an attachment process and/or a detachment process to be described later.

The pickup unit 40 is a unit that picks up the dies 71 one by one from a dicing tape 43a adhered to a dicing frame 43. The pickup unit 40 can include a pickup head 41 and a frame holder 42. The dicing frame 43 is held by the frame holder 42. A plurality of dies 71 are arranged on the dicing tape 43a adhered to the dicing frame 43. The pickup head 41 is configured to be movable in the Z direction, and picks up one die 71 from the plurality of dies 71 on the dicing tape 43a. More specifically, the pickup head 41 moves in the −Z direction to hold the die 71 on the dicing tape 43a, and moves in the +Z direction to pick up the die 71 from the dicing tape 43a. The pickup head 41 is also configured to be movable in the X and Y directions. The pickup head 41 having picked up the die 71 moves from the pickup unit 40 to the bonding unit 50 to convey the die 71 onto an intermediate stage 52 in the bonding unit 50.

The bonding unit 50 is a unit that bonds the die 71 onto the substrate 72. The bonding unit 50 can include a bonding head 51, the intermediate stage 52, a substrate stage 53, a die image capturing device 54, and a substrate image capturing device 55. The bonding head 51 is configured to be movable in the Z direction while holding the die 71. The intermediate stage 52 is configured to be movable on a base plate 56 in the X and Y directions while holding the die 71 conveyed by the pickup head 41. The substrate stage 53 is configured to be movable on the base plate 56 in the X and Y directions while holding the substrate 72. The die image capturing device 54 is arranged on, for example, the substrate stage 53 and captures the image of the bonding surface of the die 71 held by the bonding head 51. The substrate image capturing device 55 captures the image of the bonding target surface of the substrate 72 held by the substrate stage 53.

When the die 71 is conveyed onto the intermediate stage 52 by the pickup head 41, the intermediate stage 52 moves on the base plate 56 to arrange the die 71 below the bonding head 51. The bonding head 51 moves in the −Z direction to hold the die 71 on the intermediate stage 52, and moves in the +Z direction while holding the die 71. Then, the substrate stage 53 moves on the base plate 56 to arrange, below the bonding head 51, the target region of the substrate 72 to which the die 71 is bonded. After the die 71 held by the bonding head 51 and the target region of the substrate 72 are aligned by moving the substrate stage 53, the bonding head 51 moves in the −Z direction to bond the die 71 onto the target region of the substrate 72. Alignment between the die 71 and the substrate 72 can be performed based on, for example, the image of the bonding surface of the die 71 obtained by the die image capturing device 54 and the image of the bonding target surface of the substrate 72 obtained by the substrate image capturing device 55.

Here, in the bonding apparatus 100, a chuck 10 to be brought into contact with the die 71 and a holder 20 (first holder) for holding the chuck 10 can be provided in at least one of the units that hold the die 71. In the arrangement example shown in FIG. 1, the units that hold the die 71 include the pickup head 41, the bonding head 51, and the intermediate stage 52, and the chuck 10 and the holder 20 are provided in at least one of the units. As an example, an arrangement example of the pickup head 41 including the chuck 10 and the holder 20 will be described below. In this embodiment, an example of using a collet chuck (to be sometimes referred to as “collet” for short) as the chuck 10 will be described. Hereinafter, the chuck 10 may be referred to as the “collet 10”, and the holder 20 for holding the collet 10 may be referred to as the “collet holder 20”.

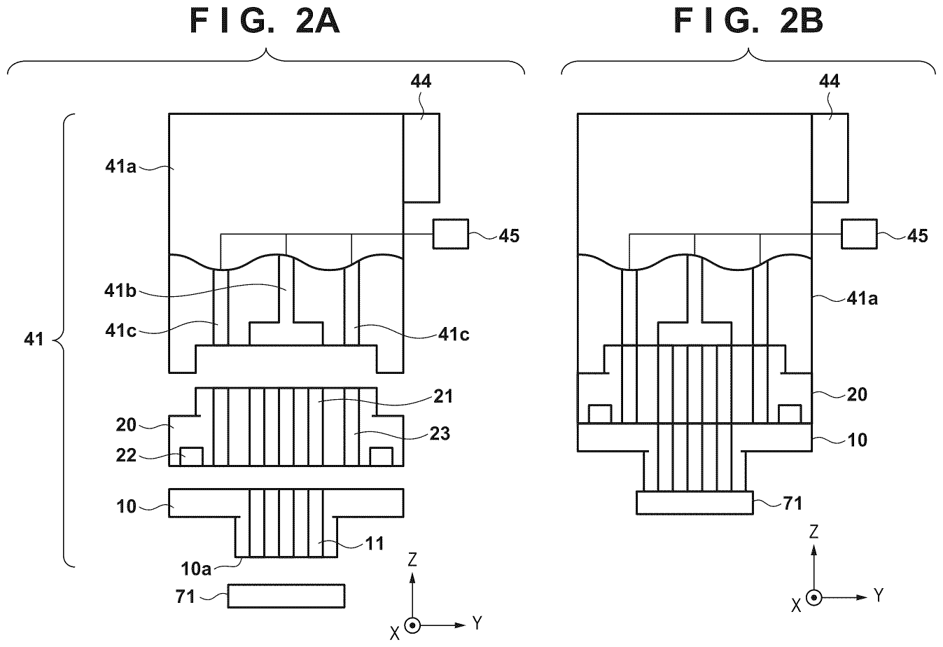

FIGS. 2A and 2B show an arrangement example of the pickup head 41 including the collet 10 and the collet holder 20. The pickup head 41 can be broadly divided into the collet 10, the collet holder 20 for holding the collet 10, and a head main body 41a for holding the collet holder 20. FIG. 2A shows a state in which the collet 10, the collet holder 20, and the head main body 41a are separated, and FIG. 2B shows a state in which the collet 10, the collet holder 20, and the head main body 41a are integrated. The pickup head 41 can be configured to be movable in the Z direction when the head main body 41a is driven in the Z direction by a driving mechanism 44.

The collet holder 20 is constantly held by the head main body 41a. Flow paths 41b and 41c communicating with a vacuum source 45 are provided in the head main body 41a, and a negative pressure (vacuum suction force) for holding the die 71 is provided from the vacuum source 45 to the flow paths 41b and 41c. A flow path 21 is provided in the collet holder 20. The flow path 21 in the collet holder 20 is arranged to communicate with the flow path 41b in the head main body 41a when the collet holder 20 is held by the head main body 41a. In the collet holder 20 shown in FIGS. 2A and 2B, a first permanent magnet 22 (to be described later) that generates a suction force (magnetic force) which attracts the collet 10, and a first negative pressure generator 23 (to be described later) formed by the flow path communicating with the vacuum source 45 are provided. The flow path as the first negative pressure generator 23 is arranged to communicate with the flow path 41c in the head main body 41a when the collet holder 20 is held by the head main body 41a.

The collet 10 is held by the collet holder 20 in the bonding process. A flow path 11 is provided in the collet 10. The flow path 11 in the collet 10 is arranged to communicate with the flow path 21 in the collet holder 20 when the collet 10 is held by the collet holder 20. With this, a negative pressure is provided from the vacuum source 45 to the flow path 11 in the collet 10 via the flow path 41b in the head main body 41a and the flow path 21 in the collet holder 20, and the die 71 in contact with a contact surface 10a of the collet 10 can be held by the pickup head 41.

In the example shown in FIGS. 2A and 2B, the first permanent magnet 22 is provided in the collet holder 20, but the first permanent magnet 22 may be provided in the collet 10. That is, the first permanent magnet that generates a suction force (magnetic force) which makes the collet 10 and the collet holder 20 attract each other can be provided in at least one of the collet 10 and the collet holder 20. The first permanent magnet is provided to compensate for the self-weight of the collet 10, that is, to prevent the collet 10 from falling off from the collet holder 20 even when the bonding apparatus 100 stops.

The above-described arrangement example of the pickup head 41 is adoptable for the bonding head 51 and the intermediate stage 52. The arrangement examples of the collet 10, the collet holder 20, and an exchange holder 30 (Examples 1 to 6 of this embodiment and Modifications 1 and 2 of the second embodiment) to be described later are also adoptable for not only the pickup head 41 but also the bonding head 51 and the intermediate stage 52. The collet 10 and the collet holder 20 may be formed as common parts among the pickup head 41, the bonding head 51, and the intermediate stage 52, or may be formed as different parts (shapes or structures) for each unit. Note that the arrangement example of the pickup head 41 is merely an example and do not intend to limit the form of the present invention.

The collet 10 may be exchanged in accordance with the type (for example, size) of the die 71 or due to damage or contamination of the collet 10. Therefore, as shown in FIG. 1, a collet exchange unit 60 configured to exchange the collet 10 is provided in the bonding apparatus 100. The collet exchange unit 60 is used to perform an attachment process of attaching the collet 10 to the collet holder 20 and/or a detachment process of detaching the collet 10 from the collet holder 20. An arrangement example of the collet exchange unit 60 in this embodiment will be described below.

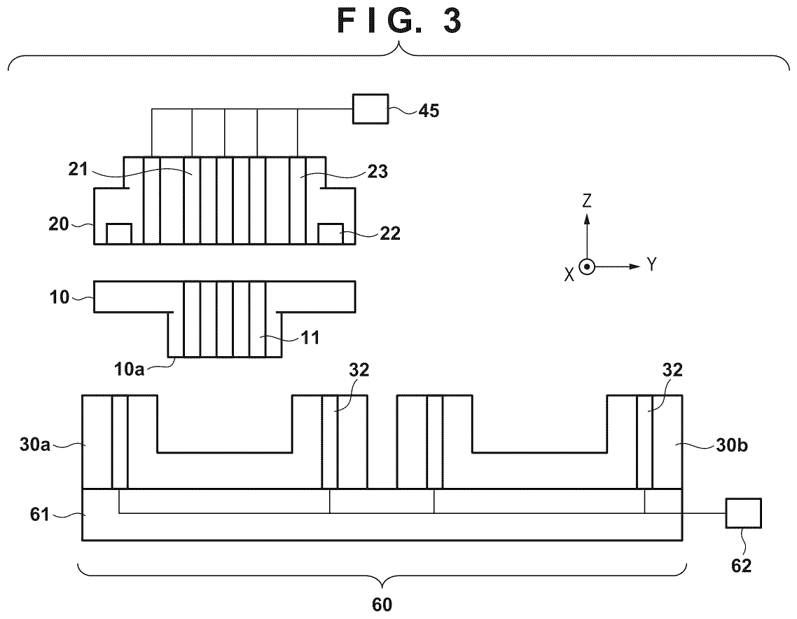

FIG. 3 shows an arrangement example of the collet exchange unit 60. FIG. 3 also shows the collet 10 and the collet holder 20. The collet exchange unit 60 can include a collet supply device 30a, a collet discard device 30b, and a main body portion 61.

The collet supply device 30a holds the collet 10 to be newly attached to the collet holder 20 in the attachment process, and supplies the collet 10 to the collet holder 20. The collet discard device 30b holds the collet 10 received from the collet holder 20 in the detachment process, and discards the collet 10. The collet supply device 30a and the collet discard device 30b may have similar arrangements. In the example shown in FIG. 3, a second negative pressure generator 32 (to be described later) formed from a flow path communicating with a vacuum source 62 is provided in each of the collet supply device 30a and the collet discard device 30b.

The main body portion 61 supports the collet supply device 30a and the collet discard device 30b. The main body portion 61 may be formed as a driving mechanism that drives the collet supply device 30a and the collet discard device 30b in the X and Y directions. With this, the collet holder 20 and the collet exchange unit 60 can be aligned to arrange the collet supply device 30a below the collet holder 20 in the attachment process. Alternatively, the collet holder 20 and the collet exchange unit 60 can be aligned to arrange the collet discard device 30b below the collet holder 20 in the detachment process. Note that this alignment may be performed by a driving mechanism that drives the unit (for example, the pickup head 41, the bonding head 51, or the intermediate stage 52) that holds the die 71, in addition to or instead of the driving mechanism (main body portion 61) of the collet exchange unit 60. That is, it may be understood that the alignment between the collet holder 20 and the collet exchange unit 60 in the attachment process and/or the detachment process is performed by a driving mechanism that relatively drives the collet holder 20 and the collet exchange unit 60.

Here, each of the collet supply device 30a and the collet discard device 30b functions as a holder (second holder) that holds the collet 10 in the attachment process and/or the detachment process. The collet supply device 30a and the collet discard device 30b may be collectively referred to as the “exchange holder 30” below. The exchange holder 30 is configured to hold the collet 10 so as not to contact the contact surface 10a of the collet 10. In the example shown in FIG. 3, roles are assigned such that one (collet supply device 30a) of multiple (two) exchange holders 30 performs the attachment process and the other (collet discard device 30b) performs the detachment process. However, the present invention is not limited to this. For example, one or more exchange holders 30 each of which can perform both the attachment process and the detachment process may be provided.

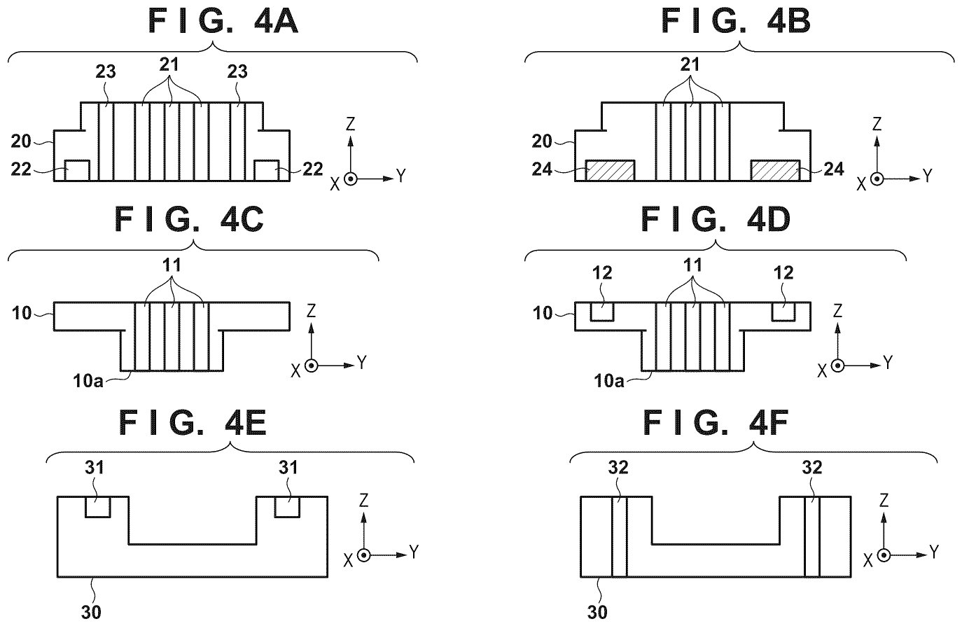

Next, specific arrangement examples of the collet 10, the collet holder 20, and the exchange holder 30 in this embodiment will be described. FIGS. 4A to 4G show representative examples of the specific arrangement of each of the collet 10, the collet holder 20, and the exchange holder 30. FIGS. 4A and 4B show representative examples of the specific arrangement of the collet holder 20, and FIGS. 4C and 4D show representative examples of the specific arrangement of the collet 10. FIGS. 4E to 4G show representative examples of the specific arrangement of the exchange holder 30. For example, one of the collet holders 20 shown in FIGS. 4A and 4B, one of the collets 10 shown in FIGS. 4C and 4D, and one of the exchange holders 30 shown in FIGS. 4E to 4G can be selectively combined and applied to the bonding apparatus 100.

As has been described above, the collet 10 is held by the collet holder 20, and comes into contact with the die 71 to suck and hold the die 71. The collet 10 includes the flow path 11 that communicates with the vacuum source 45 via the flow path 21 in the collet holder 20 when the collet 10 is held by the collet holder 20. The collet 10 may be formed from a plurality of parts or a single part. The collet holder 20 is held by at least one of units that hold the die 71. Examples of the unit that holds the die 71 are the pickup head 41, the bonding head 51, and the intermediate stage 52.

The first permanent magnet that generates a suction force (magnetic force) which makes the collet 10 and the collet holder 20 attract each other is provided in at least one of the collet 10 and the collet holder 20. The first permanent magnet is provided to compensate for the self-weight of the collet 10, that is, to prevent the collet 10 from falling off from the collet holder 20 even when the bonding apparatus 100 stops. With this, in this embodiment, it is possible to prevent the collet 10 from falling off from the collet holder 20 when the bonding apparatus 100 stops without fixing the collet 10 to the collet holder 20 by a method such as bolting, gluing, or mechanical clamping.

If the first permanent magnet 22 is provided in the collet holder 20 as shown in FIG. 4A, no permanent magnet may be provided in the collet 10 as shown in FIG. 4C. In this case, the collet 10 can include a magnetic material. If a first permanent magnet 12 is provided in the collet 10 as shown in FIG. 4D, no permanent magnet may be provided in the collet holder 20 as shown in FIG. 4B. In this case, the collet holder 20 can include a magnetic material. Each of the first permanent magnets 12 and 22 is responsible for at least part of the attraction force acting between the collet 10 and the collet holder 20.

The collet holder 20 can include a first changer configured to change the attraction force acting between the collet 10 and the collet holder 20. The attraction force acting between the collet 10 and the collet holder 20 may be understood as a suction force that makes the collet 10 and the collet holder 20 attract each other, and will be sometimes referred to as the “first attraction force” below.

The collet holder 20 shown in FIG. 4A includes, as the first changer, the first negative pressure generator 23 that generates a negative force (vacuum suction force) which attracts the collet 10. The first negative pressure generator 23 is formed as a flow path (suction hole) communicating with the vacuum source 45, and may be understood as a unit including the vacuum source 45. The controller CNT can change the first attraction force by controlling the negative pressure generated by the first negative pressure generator 23 (vacuum source 45). The collet holder 20 shown in FIG. 4B includes, as the first changer, a first electromagnet 24 that generates a suction force (magnetic force) which attracts the collet 10. The controller CNT can change the first attraction force by controlling the suction force generated by the first electromagnet 24. Note that in this embodiment, the controller CNT is configured to control the first changer (the first negative pressure generator 23 or the first electromagnet 24), but the present invention is not limited to this. If the collet holder 20 individually includes a controller, this controller may be configured to control the first changer.

The exchange holder 30 can include a second permanent magnet 31 that generates an attraction force acting between the collet 10 and the exchange holder 30 and/or a second changer configured to change the attraction force. The attraction force acting between the collet 10 and the exchange holder 30 may be understood as a suction force which makes the collet 10 and the exchange holder 30 attract each other, and will be sometimes referred to as the “second attraction force” below.

The exchange holder 30 shown in FIG. 4E includes the second permanent magnet 31 that generates a suction force (magnetic force) which attracts the collet 10. The suction force (magnetic force) generated by the second permanent magnet 31 to make the collet 10 and the exchange holder 30 attract each other is larger than the suction force (magnetic force) generated by the first permanent magnet 12 or 22 to make the collet 10 and the collet holder 20 attract each other. If the second permanent magnet 31 is provided in the exchange holder 30, the collet 10 can include a magnetic material.

The exchange holder 30 shown in FIG. 4F includes, as the second changer, the second negative pressure generator 32 that generates a negative pressure (vacuum suction force) which attracts the collet 10. The second negative pressure generator 32 is formed as a flow path (suction hole) communicating with the vacuum source 62, and may be understood as a unit including the vacuum source 62. The controller CNT can change the second attraction force by controlling the negative pressure generated by the second negative pressure generator 32 (vacuum source 62). The exchange holder 30 shown in FIG. 4G includes, as the second changer, a second electromagnet 33 that generates a suction force (magnetic force) which attracts the collet 10. The controller CNT can change the second attraction force by controlling the suction force generated by the second electromagnet 33. Note that in this embodiment, the controller CNT is configured to control the second changer (the second negative pressure generator 32 or the second electromagnet 33), but the present invention is not limited to this. If the exchange holder 30 individually includes a controller, this controller may be configured to control the second changer.

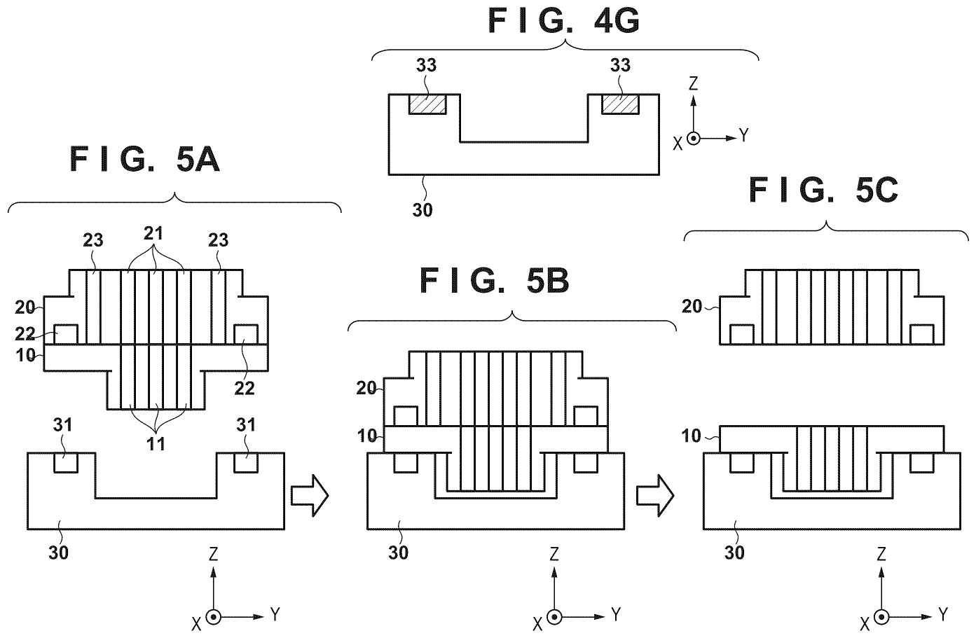

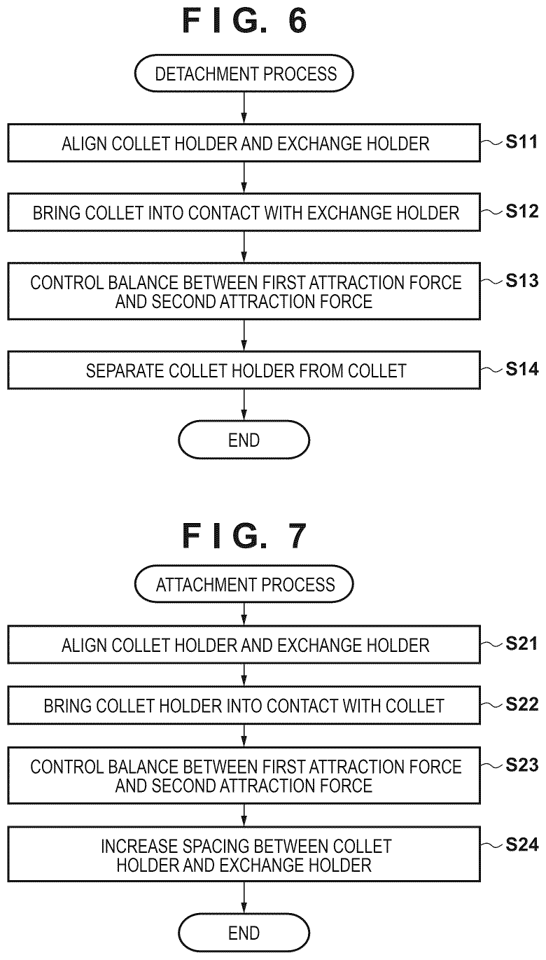

Next, the detachment process of detaching the collet 10 from the collet holder 20 using the exchange holder 30 will be described. FIGS. 5A to 5C are views showing a specific example of the detachment process. FIGS. 5A to 5C show an example of using the collet holder 20 shown in FIG. 4A, the collet 10 shown in FIG. 4C, and the exchange holder 30 shown in FIG. 4E. FIG. 6 is a flowchart illustrating the detachment process. The detachment process can be controlled by the controller CNT.

In step S11, the controller CNT aligns the collet holder 20 and the exchange holder 30 such that the collet holder 20 holding the collet 10 is arranged above the exchange holder 30 (see FIG. 5A). This alignment can be performed by relatively driving the collet holder 20 and the exchange holder 30 by using the driving mechanism for the main body portion 61 of the collet exchange unit 60 and/or the driving mechanism for the unit that holds the die 71.

In step S12, the controller CNT decreases the spacing between the collet holder 20 and the exchange holder 30, thereby bringing the collet 10 held by the collet holder 20 into contact with the exchange holder 30 (see FIG. 5B). Driving for decreasing the spacing between the collet holder 20 and the exchange holder 30 can be performed by relatively driving the collet holder 20 and the exchange holder 30 by using the driving mechanism for the collet exchange unit 60 and/or the driving mechanism for the unit that holds the die 71.

In step S13, the controller CNT controls the balance (relationship) between the first attraction force and the second attraction force to set the second attraction force larger than the first attraction force. In the example shown in FIG. 5B, the suction force (magnetic force) of the second permanent magnet 31 in the exchange holder 30 is larger than the suction force (magnetic force) of the first permanent magnet 22 in the collet holder 20. Therefore, the controller CNT can set the second attraction force larger than the first attraction force by decreasing (for example, turning off) the negative pressure generated by the first negative pressure generator 23.

In step S14, the controller CNT increases the spacing between the collet holder 20 and the exchange holder 30, thereby separating the collet holder 20 from the collet 10 (see FIG. 5C). Driving for increasing the spacing between the collet holder 20 and the exchange holder 30 can be performed by relatively driving the collet holder 20 and the exchange holder 30 by using the driving mechanism for the collet exchange unit 60 and/or the driving mechanism for the unit that holds the die 71.

Next, the attachment process of attaching the collet 10 to the collet holder 20 by using the exchange holder 30 will be described. The attachment process may be regarded as the reverse of the detachment process. FIG. 7 is a flowchart illustrating the attachment process. The attachment process can be controlled by the controller CNT.

In step S21, the controller CNT aligns the collet holder 20 and the exchange holder 30 such that the exchange holder 30 holding the collet 10 is arranged below the collet holder 20 (see FIG. 5C). In step S22, the controller CNT decreases the spacing between the collet holder 20 and the exchange holder 30, thereby bringing the collet holder 20 into contact with the collet 10 held by the exchange holder 30 (see FIG. 5B).

In step S23, the controller CNT controls the balance between the first attraction force and the second attraction force so as to set the first attraction force larger than the second attraction force. In the example shown in FIG. 5B, the suction force (magnetic force) of the second permanent magnet 31 in the exchange holder 30 is larger than the suction force (magnetic force) of the first permanent magnet 22 in the collet holder 20. Therefore, the controller CNT can set the first attraction force larger than the second attraction force by increasing (for example, turning on) the negative pressure generated by the first negative pressure generator 23. Then, in step S24, the controller CNT increases the spacing between the collet holder 20 and the exchange holder 30 (see FIG. 5A). With this, the collet 10 is attached to the collet holder 20.

The examples described above are the basic attachment process and the basic detachment process in the bonding apparatus 100 of this embodiment. Note that there are a plurality of kinds of the arrangements of the collet 10, the collet holder 20, and the exchange holder 30 in addition to those shown in FIGS. 4A to 4G. According to a selective combination of the arrangements, the method of the attachment process and/or the detachment process can be changed. Examples of the selective combination of the collet 10, the collet holder 20, and the exchange holder 30 will be described below. Note that the first changer is the first attraction force generating mechanism that generates the first attraction force acting between the holder 20 (first holder) and the collet 10 (chuck). The second changer is the second attraction force generating mechanism that generates the second attraction force acting between the exchange holder 30 (second holder) and the collet 10 (chuck). Note that “changing the attraction force” is synonymous with “adjusting the attraction force”.

### Example 1

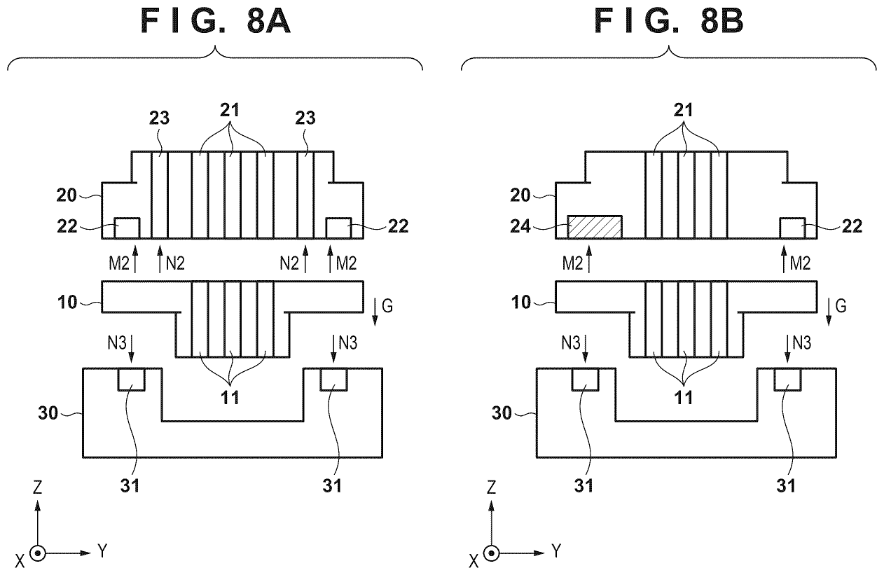

In Example 1, an example will be described in which the first permanent magnet 22 and the first changer are provided in the collet holder 20 and the second permanent magnet 31 is provided in the exchange holder 30. FIG. 8A shows an example in which the first negative pressure generator 23 is provided as the first changer in the collet holder 20. FIG. 8B shows an example in which the first electromagnet 24 is provided as the first changer in the collet holder 20.

In Example 1, the collet 10 includes a magnetic material, and self-weight compensation of the collet 10 is performed by the first permanent magnet 22 in the collet holder 20. The collet holder 20 holds the collet 10 by, in addition to the suction force (magnetic force) of the first permanent magnet 22, the suction force (negative pressure or vacuum suction force) generated by the first negative pressure generator 23 in FIG. 8A or the suction force (magnetic force) generated by the first electromagnet 24 in FIG. 8B. The exchange holder 30 holds the collet 10 by the second permanent magnet 31.

Next, the relationship of forces acting on the collet 10 will be described. For example, as shown in FIGS. 8A and 8B, let “G” be the self-weight of the collet 10, and “M2” be the suction force generated by the first permanent magnet 22 in the collet holder 20. Further, let “N2” be the suction force generated by the first negative pressure generator 23 or the first electromagnet 24 in the collet holder 20, and “N3” be the suction force generated by the second permanent magnet 31 in the exchange holder 30. In this case, the respective forces need to satisfy the following relational expressions.

$$G < M 2 , M 2 < N 3 + G , N 3 + G < M 2 + N 2$$

Next, the attachment process will be described. The attachment process is started in a state in which the collet 10 is held by the exchange holder 30. After the collet holder 20 and the exchange holder 30 are aligned, the collet holder 20 is lowered. Then, when the collet holder 20 contacts the collet 10 held by the exchange holder 30, the suction force N2 of the first negative pressure generator 23 or the first electromagnet 24 in the collet holder 20 is increased (for example, turned on). In this case, the suction force N2 of the first negative pressure generator 23 or the first electromagnet 24 is preferably kept off until the collet holder 20 completely contacts the collet 10.

When the suction force N2 of the first negative pressure generator 23 or the first electromagnet 24 in the collet holder 20 is turned on, the first attraction force acting between the collet 10 and the collet holder 20 corresponds to the sum of the suction force M2 of the first permanent magnet 22 and the suction force N2 (M2+N2). On the other hand, the second attraction force acting between the collet 10 and the exchange holder 30 corresponds to the sum of the suction force N3 of the second permanent magnet 31 and the self-weight G of the collet 10 (N3+G). As a result, the balance between the first attraction force and the second attraction force is expressed as (N3+G<M2+N2). That is, the suction force N2 of the first negative pressure generator 23 or the first electromagnet 24 is controlled so as to satisfy the above-described relational expression (N3+G<M2+N2), that is, so as to set the first attraction force larger than the second attraction force. When the collet holder 20 is lifted in this state, the collet 10 is attached to the collet holder 20.

Next, the detachment process will be described. The detachment process is started in a state in which the collet 10 is held by the collet holder 20. After the collet holder 20 and the exchange holder 30 are aligned, the collet holder 20 is lowered. Then, when the collet 10 held by the collet holder 20 contacts the exchange holder 30, the suction force N2 of the first negative pressure generator 23 or the first electromagnet 24 in the collet holder 20 is decreased (for example, turned off). In this case, the suction force N2 of the first negative pressure generator 23 or the first electromagnet 24 is preferably kept on until the collet 10 completely contacts the exchange holder 30.

When the suction force N2 of the first negative pressure generator 23 or the first electromagnet 24 in the collet holder 20 is turned off, the first attraction force acting between the collet 10 and the collet holder 20 is only the suction force M2 of the first permanent magnet 22. On the other hand, the second attraction force acting between the collet 10 and the exchange holder 30 corresponds to the sum of the suction force N3 of the second permanent magnet 31 and the self-weight G of the collet 10 (N3+G). As a result, the balance between the first attraction force and the second attraction force is expressed as (M2<N3+G). That is, the suction force N2 of the first negative pressure generator 23 or the first electromagnet 24 is controlled so as to satisfy the above-described relational expression (M2<N3+G), that is, so as to set the second attraction force larger than the first attraction force. When the collet holder 20 is lifted in this state, the collet 10 is detached from the collet holder 20 and held by the exchange holder 30.

In this manner, in Example 1, the attachment process and the detachment process are performed by controlling the suction force of the first negative pressure generator 23 or the first electromagnet 24 provided in the collet holder 20. Here, control of the suction force of the first electromagnet 24 is not limited to ON/OFF control of the suction force of the first electromagnet 24, and may be performed by switching control between the N pole and the S pole of the first electromagnet 24.

### Example 2

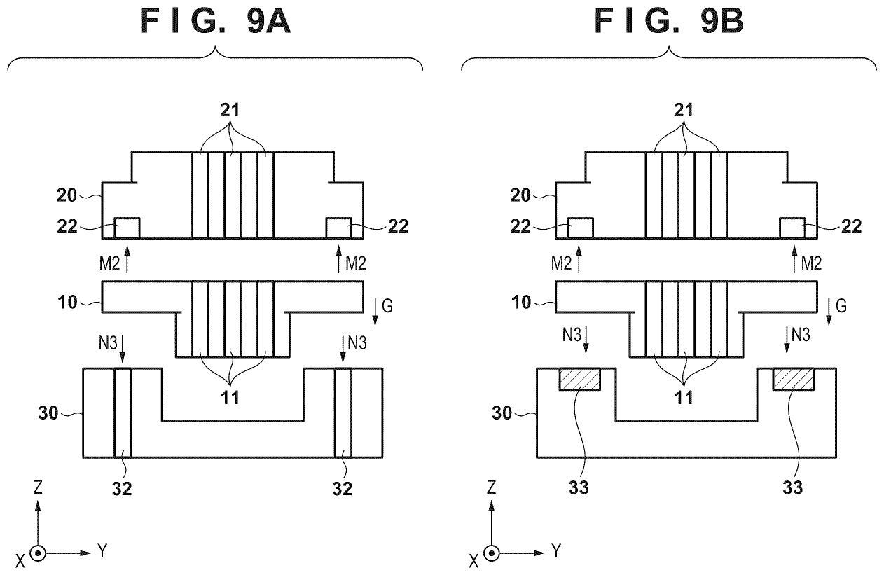

In Example 2, an example will be described in which the first permanent magnet 22 is provided in the collet holder 20 and the second changer is provided in the exchange holder 30. FIG. 9A shows an example in which the second negative pressure generator 32 is provided as the second changer in the exchange holder 30. FIG. 9B shows an example in which the second electromagnet 33 is provided as the second changer in the exchange holder 30.

In Example 2, the collet 10 includes a magnetic material, and self-weight compensation of the collet 10 is performed by the first permanent magnet 22 in the collet holder 20. The first permanent magnet 22 in the collet holder 20 also allows the collet holder 20 to hold the collet 10. The exchange holder 30 holds the collet 10 by the suction force (negative pressure or vacuum suction force) generated by the second negative pressure generator 32 in FIG. 9A or the suction force (magnetic force) generated by the second electromagnet 33 in FIG. 9B.

Next, the relationship of forces acting on the collet 10 will be described. For example, as shown in FIGS. 9A and 9B, let “G” be the self-weight of the collet 10, “M2” be the suction force generated by the first permanent magnet 22 in the collet holder 20, and “N3” be the suction force generated by the second negative pressure generator 32 or the second electromagnet 33 in the exchange holder 30. In this case, the respective forces need to satisfy the following relational expressions.

$$G < M 2 , M 2 < N 3 + G$$

Next, the attachment process will be described. The attachment process is started in a state in which the collet 10 is held by the exchange holder 30. After the collet holder 20 and the exchange holder 30 are aligned, the collet holder 20 is lowered. Then, when the collet holder 20 contacts the collet 10 held by the exchange holder 30, the suction force N3 of the second negative pressure generator 32 or the second electromagnet 33 in the exchange holder 30 is decreased (for example, turned off). In this case, the suction force N3 of the second negative pressure generator 32 or the second electromagnet 33 is preferably kept on until the collet holder 20 completely contacts the collet 10.

When the suction force N3 of the second negative pressure generator 32 or the second electromagnet 33 in the exchange holder 30 is turned off, the second attraction force acting between the collet 10 and the exchange holder 30 is only the self-weight G of the collet 10. On the other hand, the first attraction force acting between the collet 10 and the collet holder 20 is the suction force M2 of the first permanent magnet 22. As a result, the balance between the first attraction force and the second attraction force is expressed as (G<M2). That is, the suction force N3 of the second negative pressure generator 32 or the second electromagnet 33 is controlled so as to satisfy the above-described relational expression (G<M2), that is, so as to set the first attraction force larger than the second attraction force. When the collet holder 20 is lifted in this state, the collet 10 is attached to the collet holder 20.

Next, the detachment process will be described. The detachment process is started in a state in which the collet 10 is held by the collet holder 20. After the collet holder 20 and the exchange holder 30 are aligned, the collet holder 20 is lowered. Then, when the collet 10 held by the collet holder 20 contacts the exchange holder 30, the suction force N3 of the second negative pressure generator 32 or the second electromagnet 33 in the exchange holder 30 is increased (for example, turned on). In this case, the suction force N3 of the second negative pressure generator 32 or the second electromagnet 33 is preferably kept off until the collet 10 completely contacts the exchange holder 30.

When the suction force N3 of the second negative pressure generator 32 or the second electromagnet 33 in the exchange holder 30 is turned on, the second attraction force acting between the collet 10 and the exchange holder 30 corresponds to the sum of the suction force N3 and the self-weight G of the collet 10 (N3+G). On the other hand, the first attraction force acting between the collet 10 and the collet holder 20 is only the suction force M2 of the first permanent magnet 22. As a result, the balance between the first attraction force and the second attraction force is expressed as (M2<N3+G). That is, the suction force N3 of the second negative pressure generator 32 or the second electromagnet 33 is controlled so as to satisfy the above-described relational expression (M2<N3+G), that is, so as to set the second attraction force larger than the first attraction force. When the collet holder 20 is lifted in this state, the collet 10 is detached from the collet holder 20 and held by the exchange holder 30.

In this manner, in Example 2, the attachment process and the detachment process are performed by controlling the suction force of the second negative pressure generator 32 or the second electromagnet 33 provided in the exchange holder 30. Here, control of the suction force of the second electromagnet 33 is not limited to ON/OFF control of the suction force of the second electromagnet 33, and may be performed by switching control between the N pole and the S pole of the second electromagnet 33.

### Example 3

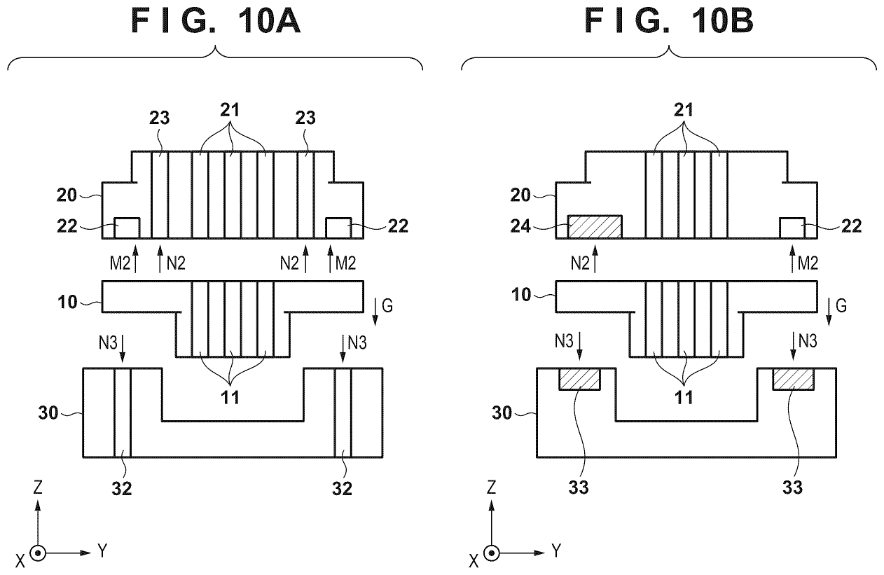

In Example 3, an example will be described in which the first permanent magnet 22 and the first changer are provided in the collet holder 20 and the second changer is provided in the exchange holder 30. FIG. 10A shows an example in which the first negative pressure generator 23 is provided as the first changer in the collet holder 20 and the second negative pressure generator 32 is provided as the second changer in the exchange holder 30. FIG. 10B shows an example in which the first electromagnet 24 is provided as the first changer in the collet holder 20 and the second electromagnet 33 is provided as the second changer in the exchange holder 30.

In Example 3, the collet 10 includes a magnetic material, and self-weight compensation of the collet 10 is performed by the first permanent magnet 22 in the collet holder 20. The collet holder 20 holds the collet 10 by, in addition to the suction force (magnetic force) of the first permanent magnet 22, the suction force (negative pressure or vacuum suction force) generated by the first negative pressure generator 23 in FIG. 10A or the suction force (magnetic force) generated by the first electromagnet 24 in FIG. 10B. The exchange holder 30 holds the collet 10 by the suction force (negative pressure or vacuum suction force) generated by the second negative pressure generator 32 in FIG. 10A or the suction force (magnetic force) generated by the second electromagnet 33 in FIG. 10B.

Next, the relationship of forces acting on the collet 10 will be described. For example, as shown in FIGS. 10A and 10B, let “G” be the self-weight of the collet 10, and “M2” be the suction force generated by the first permanent magnet 22 in the collet holder 20. Further, let “N2” be the suction force generated by the first negative pressure generator 23 or the first electromagnet 24 in the collet holder 20, and “N3” be the suction force generated by the second negative pressure generator 32 or the second electromagnet 33 in the exchange holder 30. In this case, the respective forces need to satisfy the following relational expressions.

$$G < M 2 , M 2 < N 3 + G$$

Next, the attachment process will be described. The attachment process is started in a state in which the collet 10 is held by the exchange holder 30. After the collet holder 20 and the exchange holder 30 are aligned, the collet holder 20 is lowered. Then, when the collet holder 20 contacts the collet 10 held by the exchange holder 30, the suction force N2 of the first negative pressure generator 23 or the first electromagnet 24 in the collet holder 20 is increased (for example, turned on). In this case, the suction force N2 of the first negative pressure generator 23 or the first electromagnet 24 is preferably kept off until the collet holder 20 completely contacts the collet 10. Further, the suction force N3 of the second negative pressure generator 32 or the second electromagnet 33 in the exchange holder 30 is preferably kept on until the collet holder 20 contacts the collet 10 on the exchange holder 30, and turned off when the collet holder 20 contacts the collet 10.

When the suction force N2 of the first negative pressure generator 23 or the first electromagnet 24 in the collet holder 20 is turned on, the first attraction force acting between the collet 10 and the collet holder 20 corresponds to the sum of the suction force M2 of the first permanent magnet 22 and the suction force N2 (M2+N2). On the other hand, the second attraction force acting between the collet 10 and the exchange holder 30 is only the self-weight G of the collet 10 since the suction force N3 of the second negative pressure generator 32 or the second electromagnet 33 in the exchange holder 30 is turned off. As a result, the balance between the first attraction force and the second attraction force is expressed as (G<M2+N2). That is, the suction force N2 of the first negative pressure generator 23 or the first electromagnet 24 and the suction force N3 of the second negative pressure generator 32 or the second electromagnet 33 are controlled so as to satisfy the above-described relational expression (G<M2), that is, so as to set the first attraction force larger than the second attraction force. When the collet holder 20 is lifted in this state, the collet 10 is attached to the collet holder 20. Here, according to the above-described relational expression (G<M2), it may be considered that the suction force N2 of the first negative pressure generator 23 or the first electromagnet 24 in the collet holder 20 is unnecessary. However, by adding the suction force N2, it is possible to minimize the suction force M2 of the first permanent magnet 22.

Next, the detachment process will be described. The detachment process is started in a state in which the collet 10 is held by the collet holder 20. After the collet holder 20 and the exchange holder 30 are aligned, the collet holder 20 is lowered. Then, when the collet 10 held by the collet holder 20 contacts the exchange holder 30, the suction force N3 of the second negative pressure generator 32 or the second electromagnet 33 in the exchange holder 30 is increased (for example, turned on). In this case, the suction force N3 of the second negative pressure generator 32 or the second electromagnet 33 is preferably kept off until the collet 10 completely contacts the exchange holder 30. The suction force N2 of the first negative pressure generator 23 or the first electromagnet 24 in the collet holder 20 is preferably kept on until the collet holder 20 contacts the collet 10 on the exchange holder 30, and turned off when the collet holder 20 contacts the collet 10.

When the suction force N3 of the second negative pressure generator 32 or the second electromagnet 33 in the exchange holder 30 is turned on, the second attraction force acting between the collet 10 and the exchange holder 30 corresponds to the sum of the suction force N3 and the self-weight G of the collet 10 (N3+G). On the other hand, the first attraction force acting between the collet 10 and the collet holder 20 is only the suction force M2 of the first permanent magnet 22 since the suction force N2 of the first negative pressure generator 23 or the first electromagnet 24 in the collet holder 20 is turned off. As a result, the balance between the first attraction force and the second attraction force is expressed as (M2<N3+G). That is, the suction force N2 of the first negative pressure generator 23 or the first electromagnet 24 and the suction force N3 of the second negative pressure generator 32 or the second electromagnet 33 are controlled so as to satisfy the above-described relational expression (M2<N3+G), that is, so as to set the second attraction force larger than the first attraction force. When the collet holder 20 is lifted in this state, the collet 10 is detached from the collet holder 20 and held by the exchange holder 30.

In this manner, in Example 3, the attachment process and the detachment process are performed by controlling the suction force of the first negative pressure generator 23 or the first electromagnet 24 provided in the collet holder 20 and the suction force of the second negative pressure generator 32 or the second electromagnet 33 provided in the exchange holder 30. Here, control of the suction force of the first electromagnet 24 is not limited to ON/OFF control of the suction force of the first electromagnet 24, and may be performed by switching control between the N pole and the S pole of the first electromagnet 24. Similarly, control of the suction force of the second electromagnet 33 is not limited to ON/OFF control of the suction force of the second electromagnet 33, and may be performed by switching control between the N pole and the S pole of the second electromagnet 33.

### Example 4

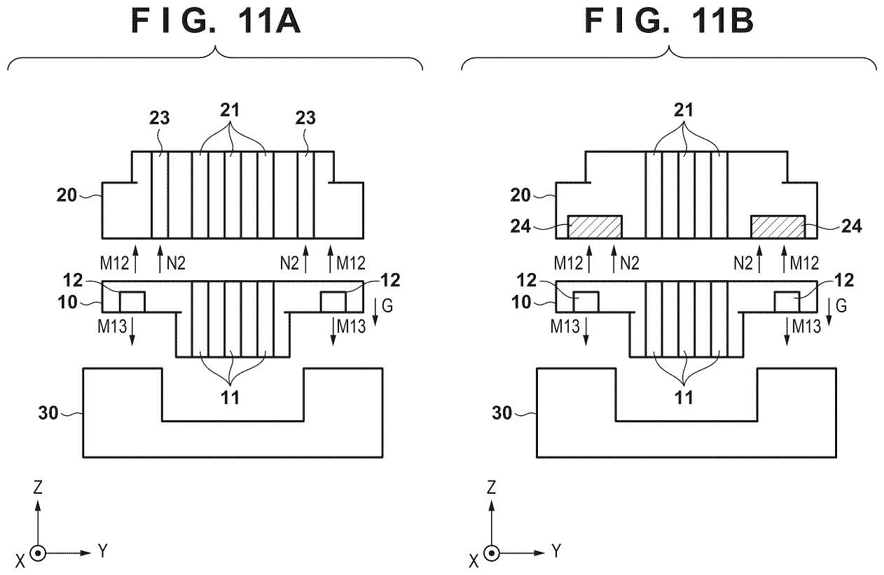

In Example 4, an example will be described in which the first permanent magnet 12 is provided in the collet 10 and the first changer is provided in the collet holder 20. FIG. 11A shows an example in which the first negative pressure generator 23 is provided as the first changer in the collet holder 20. FIG. 11B shows an example in which the first electromagnet 24 is provided as the first changer in the collet holder 20.

In Example 4, the collet holder 20 includes a magnetic material, and self-weight compensation of the collet 10 is performed by the first permanent magnet 12 in the collet 10. The collet holder 20 holds the collet 10 by, in addition to the suction force of the first permanent magnet 12, the suction force (negative pressure or vacuum suction force) generated by the first negative pressure generator 23 in FIG. 11A or the suction force (magnetic force) generated by the first electromagnet 24 in FIG. 11B. If the collet holder 20 includes the first electromagnet 24, the collet 10 includes a magnetic material. The exchange holder 30 includes a magnetic material, and the exchange holder 30 holds the collet 10 by the suction force (magnetic force) of the first permanent magnet 12 in the collet 10.

In Example 4, in a contact state in which the collet 10 is in contact with the collet holder 20 and the exchange holder 30, the suction force of the first permanent magnet 12 with respect to the magnetic material in the collet holder 20 is smaller than the suction force of the first permanent magnet 12 with respect to the magnetic material in the exchange holder 30. For example, the position of the first permanent magnet 12 in the collet 10 is adjusted such that the distance from the first permanent magnet 12 to the magnetic material in the collet holder 20 is larger than the distance from the first permanent magnet 12 to the magnetic material in the exchange holder 30 in the contact state. Alternatively, not only the position of the first permanent magnet 12 in the collet 10 but also the position of the magnetic material in the collet holder 20 and the position of the magnetic material in the exchange holder 30 may be adjusted.

Next, the relationship of forces acting on the collet 10 will be described. For example, as shown in FIGS. 11A and 11B, let “G” be the self-weight of the collet 10, and “N2” be the suction force generated by the first negative pressure generator 23 or the first electromagnet 24 in the collet holder 20. Further, let “M12” be the suction force generated by the first permanent magnet 12 in the collet 10 with respect to the collet holder 20 (magnetic material) in a state in which the collet 10 is in contact with the collet holder 20. Let “M13” be the suction force generated by the first permanent magnet 12 in the collet 10 with respect to the exchange holder 30 (magnetic material) in a state in which the collet 10 is in contact with the exchange holder 30. In this case, the respective forces need to satisfy the following relational expressions.

$$G < M 12 , G + M 13 < N 2 , M 12 < G + M 13$$

Next, the attachment process will be described. The attachment process is started in a state in which the collet 10 is held by the exchange holder 30. After the collet holder 20 and the exchange holder 30 are aligned, the collet holder 20 is lowered. Then, when the collet holder 20 contacts the collet 10 held by the exchange holder 30, the suction force N2 of the first negative pressure generator 23 or the first electromagnet 24 in the collet holder 20 is increased (for example, turned on). In this case, the suction force N2 of the first negative pressure generator 23 or the first electromagnet 24 is preferably kept off until the collet holder 20 completely contacts the collet 10.

When the suction force N2 of the first negative pressure generator 23 or the first electromagnet 24 in the collet holder 20 is turned on, the first attraction force acting between the collet 10 and the collet holder 20 corresponds to the sum of the suction force M12 of the first permanent magnet 12 in the collet 10 and the suction force N2 (M12+N2). On the other hand, the second attraction force acting between the collet 10 and the exchange holder 30 corresponds to the sum of the suction force M13 of the first permanent magnet 12 in the collet 10 and the self-weight G of the collet 10 (G+M13). As a result, the balance between the first attraction force and the second attraction force is expressed as (G+M13<M12+N2). That is, the suction force N2 of the first negative pressure generator 23 or the first electromagnet 24 is controlled so as to satisfy the above-described relational expression (G+M13<N2), that is, so as to set the first attraction force larger than the second attraction force. When the collet holder 20 is lifted in this state, the collet 10 is attached to the collet holder 20.

Next, the detachment process will be described. The detachment process is started in a state in which the collet 10 is held by the collet holder 20. After the collet holder 20 and the exchange holder 30 are aligned, the collet holder 20 is lowered. Then, when the collet 10 held by the collet holder 20 contacts the exchange holder 30, the suction force N2 of the first negative pressure generator 23 or the first electromagnet 24 in the collet holder 20 is decreased (for example, turned off). In this case, the suction force N2 of the first negative pressure generator 23 or the first electromagnet 24 is preferably kept on until the collet 10 completely contacts the exchange holder 30.

When the suction force N2 of the first negative pressure generator 23 or the first electromagnet 24 in the collet holder 20 is turned off, the first attraction force acting between the collet 10 and the collet holder 20 is only the suction force M12 of the first permanent magnet 12 in the collet 10. On the other hand, the second attraction force acting between the collet 10 and the exchange holder 30 corresponds to the sum of the suction force M13 of the first permanent magnet 12 in the collet 10 and the self-weight G of the collet 10 (G+M13). As a result, the balance between the first attraction force and the second attraction force is expressed as (M12<G+M13). That is, the suction force N2 of the first negative pressure generator 23 or the first electromagnet 24 is controlled so as to satisfy the above-described relational expression (M12<G+M13), that is, so as to set the second attraction force larger than the first attraction force. When the collet holder 20 is lifted in this state, the collet 10 is detached from the collet holder 20 and held by the exchange holder 30.

In this manner, in Example 4, the attachment process and the detachment process are performed by controlling the suction force of the first negative pressure generator 23 or the first electromagnet 24 provided in the collet holder 20. Here, control of the suction force of the first electromagnet 24 is not limited to ON/OFF control of the suction force of the first electromagnet 24, and may be performed by switching control between the N pole and the S pole of the first electromagnet 24.

### Example 5

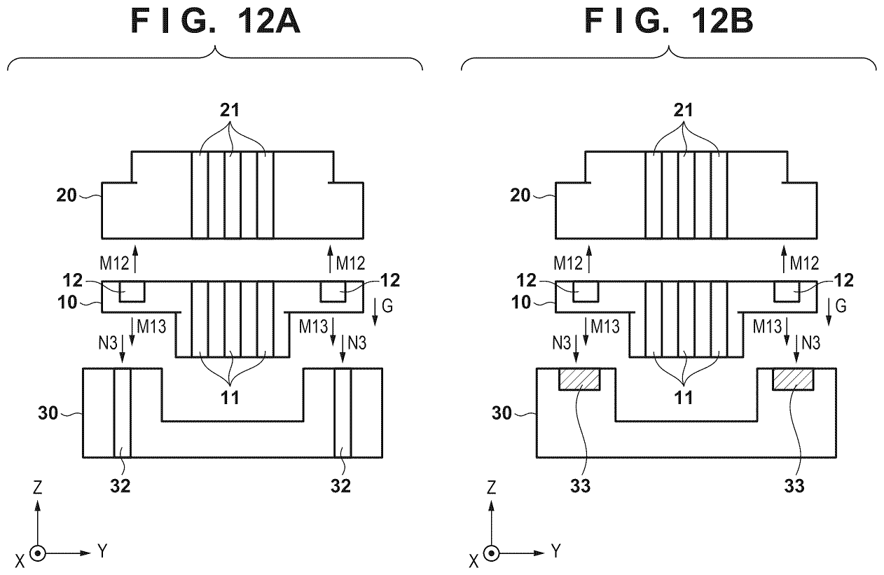

In Example 5, an example will be described in which the first permanent magnet 12 is provided in the collet 10 and the second changer is provided in the exchange holder 30. FIG. 12A shows an example in which the second negative pressure generator 32 is provided as the second changer in the exchange holder 30. FIG. 12B shows an example in which the second electromagnet 33 is provided as the second changer in the exchange holder 30.

In Example 5, the collet holder 20 includes a magnetic material, and self-weight compensation of the collet 10 is performed by the first permanent magnet 12 in the collet 10. The collet holder 20 holds the collet 10 by the suction force (magnetic force) of the first permanent magnet 12. The exchange holder 30 includes a magnetic material. The exchange holder 30 holds the collet 10 by, in addition to the suction force (magnetic force) of the first permanent magnet 12, the suction force (negative pressure or vacuum suction force) generated by the second negative pressure generator 32 in FIG. 12A or the suction force (magnetic force) generated by the second electromagnet 33 in FIG. 12B. If the exchange holder 30 includes the second electromagnet 33, the collet 10 includes a magnetic material.

In Example 5, in a contact state in which the collet 10 is in contact with the collet holder 20 and the exchange holder 30, the suction force of the first permanent magnet 12 with respect to the magnetic material in the exchange holder 30 is smaller than the suction force of the first permanent magnet 12 with respect to the magnetic material in the collet holder 20. For example, the position of the first permanent magnet 12 in the collet 10 is adjusted such that the distance from the first permanent magnet 12 to the magnetic material in the exchange holder 30 is larger than the distance from the first permanent magnet 12 to the magnetic material in the collet holder 20 in the contact state. Alternatively, not only the position of the first permanent magnet 12 in the collet 10 but also the position of the magnetic material in the collet holder 20 and the position of the magnetic material in the exchange holder 30 may be adjusted.

Next, the relationship of forces acting on the collet 10 will be described. For example, as shown in FIGS. 12A and 12B, let “G” be the self-weight of the collet 10, and “N3” be the suction force generated by the second negative pressure generator 32 or the second electromagnet 33 in the exchange holder 30. Further, let “M12” be the suction force generated by the first permanent magnet 12 in the collet 10 with respect to the collet holder 20 (magnetic material) in a state in which the collet 10 is in contact with the collet holder 20. Let “M13” be the suction force generated by the first permanent magnet 12 in the collet 10 with respect to the exchange holder 30 (magnetic material) in a state in which the collet 10 is in contact with the exchange holder 30. In this case, the respective forces need to satisfy the following relational expressions.

$$G < M 12 , G + M 13 < M 12 , M 12 < G + N 3$$

Next, the attachment process will be described. The attachment process is started in a state in which the collet 10 is held by the exchange holder 30. After the collet holder 20 and the exchange holder 30 are aligned, the collet holder 20 is lowered. Then, when the collet holder 20 contacts the collet 10 held by the exchange holder 30, the suction force N3 of the second negative pressure generator 32 or the second electromagnet 33 in the exchange holder 30 is decreased (for example, turned off). In this case, the suction force N3 of the second negative pressure generator 32 or the second electromagnet 33 is preferably kept on until the collet holder 20 completely contacts the collet 10.

When the suction force N3 of the second negative pressure generator 32 or the second electromagnet 33 in the exchange holder 30 is turned off, the second attraction force acting between the collet 10 and the exchange holder 30 corresponds to the sum of the suction force M13 of the first permanent magnet 12 in the collet 10 and the self-weight G of the collet 10 (G+M13). On the other hand, the first attraction force acting between the collet 10 and the collet holder 20 is only the suction force M12 of the first permanent magnet 12 in the collet 10. As a result, the balance between the first attraction force and the second attraction force is expressed as (G+M13<M12). That is, the suction force N3 of the second negative pressure generator 32 or the second electromagnet 33 is controlled so as to satisfy the above-described relational expression (G+M13<M12), that is, so as to set the first attraction force larger than the second attraction force. When the collet holder 20 is lifted in this state, the collet 10 is attached to the collet holder 20.

Next, the detachment process will be described. The detachment process is started in a state in which the collet 10 is held by the collet holder 20. After the collet holder 20 and the exchange holder 30 are aligned, the collet holder 20 is lowered. Then, when the collet 10 held by the collet holder 20 contacts the exchange holder 30, the suction force N3 of the second negative pressure generator 32 or the second electromagnet 33 in the exchange holder 30 is increased (for example, turned on). In this case, the suction force N3 of the second negative pressure generator 32 or the second electromagnet 33 is preferably kept off until the collet 10 completely contacts the exchange holder 30.

When the suction force N3 of the second negative pressure generator 32 or the second electromagnet 33 in the exchange holder 30 is turned on, the second attraction force acting between the collet 10 and the exchange holder 30 corresponds to the sum of the self-weight G of the collet 10 and the suction force N3 (G+N3). On the other hand, the first attraction force acting between the collet 10 and the collet holder 20 is only the suction force M12 of the first permanent magnet 12 in the collet 10. As a result, the balance between the first attraction force and the second attraction force is expressed as (M12<G+N3). That is, the suction force N3 of the second negative pressure generator 32 or the second electromagnet 33 is controlled so as to satisfy the above-described relational expression (M12<G+N3), that is, so as to set the second attraction force larger than the first attraction force. When the collet holder 20 is lifted in this state, the collet 10 is detached from the collet holder 20 and held by the exchange holder 30. Here, considering the suction force M13 of the first permanent magnet 12 in the collet 10 in the second attraction force, the balance between the first attraction force and the second attraction force is expressed as (M12<G+N3+M13). Hence, it is possible to decrease the suction force N3 by the amount corresponding to the suction force M13.

In this manner, in Example 5, the attachment process and the detachment process are performed by controlling the suction force of the second negative pressure generator 32 or the second electromagnet 33 provided in the exchange holder 30. Here, control of the suction force of the second electromagnet 33 is not limited to ON/OFF control of the suction force of the second electromagnet 33, and may be performed by switching control between the N pole and the S pole of the second electromagnet 33.

### Example 6

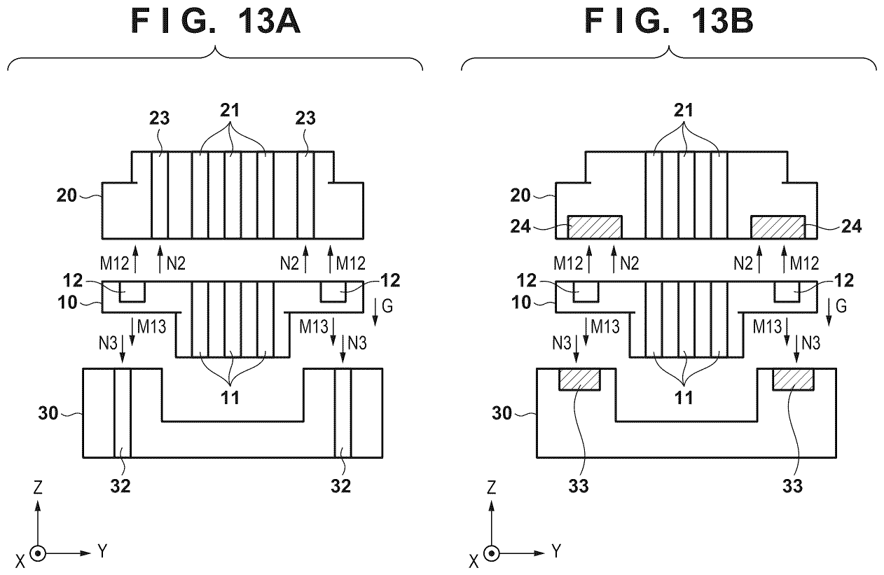

In Example 6, an example will be described in which the first permanent magnet 12 is provided in the collet 10, the first changer is provided in the collet holder 20, and the second changer is provided in the exchange holder 30. FIG. 13A shows an example in which the first negative pressure generator 23 is provided as the first changer in the collet holder 20 and the second negative pressure generator 32 is provided as the second changer in the exchange holder 30. FIG. 13B shows an example in which the first electromagnet 24 is provided as the first changer in the collet holder 20 and the second electromagnet 33 is provided as the second changer in the exchange holder 30.

In Example 6, the collet holder 20 includes a magnetic material, and self-weight compensation of the collet 10 is performed by the first permanent magnet 12 in the collet 10. The collet holder 20 holds the collet 10 by, in addition to the suction force of the first permanent magnet 12, the suction force (negative pressure or vacuum suction force) generated by the first negative pressure generator 23 in FIG. 13A or the suction force (magnetic force) generated by the first electromagnet 24 in FIG. 13B. The exchange holder 30 includes a magnetic material. The exchange holder 30 holds the collet 10 by, in addition to the suction force (magnetic force) of the first permanent magnet 12, the suction force (negative pressure or vacuum suction force) generated by the second negative pressure generator 32 in FIG. 13A or the suction force (magnetic force) generated by the second electromagnet 33 in FIG. 13B. If the collet holder 20 includes the first electromagnet 24 and/or the collet holder 30 includes the second electromagnet 33, the collet 10 includes a magnetic material.

Next, the relationship of forces acting on the collet 10 will be described. For example, as shown in FIGS. 13A and 13B, let “G” be the self-weight of the collet 10, “N2” be the suction force generated by the first negative pressure generator 23 or the first electromagnet 24 in the collet holder 20, and “N3” be the suction force generated by the second negative pressure generator 32 or the second electromagnet 33 in the exchange holder 30. Further, let “M12” be the suction force generated by the first permanent magnet 12 in the collet 10 with respect to the collet holder 20 (magnetic material) in a state in which the collet 10 is in contact with the collet holder 20. Let “M13” be the suction force generated by the first permanent magnet 12 in the collet 10 with respect to the exchange holder 30 (magnetic material) in a state in which the collet 10 is in contact with the exchange holder 30. In this case, the respective forces need to satisfy the following relational expressions.

$$G < M 12 , M 12 < G + N 3 , G + M 13 < N 2$$

Next, the attachment process will be described. The attachment process is started in a state in which the collet 10 is held by the exchange holder 30. After the collet holder 20 and the exchange holder 30 are aligned, the collet holder 20 is lowered. Then, when the collet holder 20 contacts the collet 10 held by the exchange holder 30, the suction force N2 of the first negative pressure generator 23 or the first electromagnet 24 in the collet holder 20 is increased (for example, turned on). In this case, the suction force N2 of the first negative pressure generator 23 or the first electromagnet 24 is preferably kept off until the collet holder 20 completely contacts the collet 10. The suction force N3 of the second negative pressure generator 32 or the second electromagnet 33 in the exchange holder 30 may be kept on or off since the suction force M13 of the first permanent magnet 12 in the collet 10 is generated. Preferably, the suction force N3 is kept on until the collet holder 20 contacts the collet 10 on the exchange holder 30, and the suction force N3 is turned off when the collet holder 20 contacts the collet 10.

When the suction force N2 of the first negative pressure generator 23 or the first electromagnet 24 in the collet holder 20 is turned on, the first attraction force acting between the collet 10 and the collet holder 20 is expressed by a value including the suction force N2 (more specifically, M12+N2). On the other hand, the second attraction force acting between the collet 10 and the exchange holder 30 corresponds to the sum of the suction force M13 of the first permanent magnet 12 and the self-weight G of the collet 10 (G+M13) since the suction force N3 of the second negative pressure generator 32 or the second electromagnet 33 in the exchange holder 30 is turned off. As a result, the balance between the first attraction force and the second attraction force is expressed as (G+M13<N2). That is, the suction force N2 of the first negative pressure generator 23 or the first electromagnet 24 and the suction force N3 of the second negative pressure generator 32 or the second electromagnet 33 are controlled so as to satisfy the above-described relational expression (G+M13<N2), that is, so as to set the first attraction force larger than the second attraction force. When the collet holder 20 is lifted in this state, the collet 10 is attached to the collet holder 20.

Next, the detachment process will be described. The detachment process is started in a state in which the collet 10 is held by the collet holder 20. After the collet holder 20 and the exchange holder 30 are aligned, the collet holder 20 is lowered. Then, when the collet 10 held by the collet holder 20 contacts the exchange holder 30, the suction force N3 of the second negative pressure generator 32 or the second electromagnet 33 in the exchange holder 30 is increased (for example, turned on). In this case, the suction force N3 of the second negative pressure generator 32 or the second electromagnet 33 is preferably kept off until the collet 10 completely contacts the exchange holder 30. The suction force N2 of the first negative pressure generator 23 or the first electromagnet 24 in the collet holder 20 is preferably kept on until the collet holder 20 contacts the collet 10 on the exchange holder 30, and turned off when the collet holder 20 contacts the collet 10.

When the suction force N3 of the second negative pressure generator 32 or the second electromagnet 33 in the exchange holder 30 is turned on, the second suction force acting between the collet 10 and the exchange holder 30 is expressed by a value including the self-weight W of the collet 10 and the suction force N3 (G+N3). On the other hand, the first attraction force acting between the collet 10 and the collet holder 20 is only the suction force M12 of the first permanent magnet 12 in the collet 10 since the suction force N2 of the first negative pressure generator 23 or the first electromagnet 24 in the collet holder 20 is turned off. As a result, the balance between the first attraction force and the second attraction force is expressed as (M12<G+M13). That is, the suction force N2 of the first negative pressure generator 23 or the first electromagnet 24 and the suction force N3 of the second negative pressure generator 32 or the second electromagnet 33 are controlled so as to satisfy the above-described relational expression (M12<G+M13), that is, so as to set the second attraction force larger than the first attraction force. When the collet holder 20 is lifted in this state, the collet 10 is detached from the collet holder 20 and held by the exchange holder 30.

In this manner, in Example 6, the attachment process and the detachment process are performed by controlling the suction force of the first negative pressure generator 23 or the first electromagnet 24 provided in the collet holder 20 and the suction force of the second negative pressure generator 32 or the second electromagnet 33 provided in the exchange holder 30. Here, control of the suction force of the first electromagnet 24 is not limited to ON/OFF control of the suction force of the first electromagnet 24, and may be performed by switching control between the N pole and the S pole of the first electromagnet 24. Similarly, control of the suction force of the second electromagnet 33 is not limited to ON/OFF control of the suction force of the second electromagnet 33, and may be performed by switching control between the N pole and the S pole of the second electromagnet 33.

As has been described above, in the bonding apparatus 100 of this embodiment, the attachment process and/or the detachment process is performed by controlling the balance between the first attraction force acting between the collet 10 and the collet holder 20 and the second attraction force acting between the collet 10 and the exchange holder 30. When the first attraction force and the second attraction force are used in the attachment process and/or the detachment process as described above, an operation of sliding another member with respect to the collet 10 or the collet holder 20 is not performed. Hence, generation of particles in the bonding apparatus 100 can be reduced.

### Second Embodiment

The second embodiment according to the present invention will be described. In this embodiment, modifications of the second changer that can be provided in an exchange holder 30 will be described. Note that this embodiment basically takes over the first embodiment, and matters not mentioned below can follow the first embodiment.

### [Modification 1]

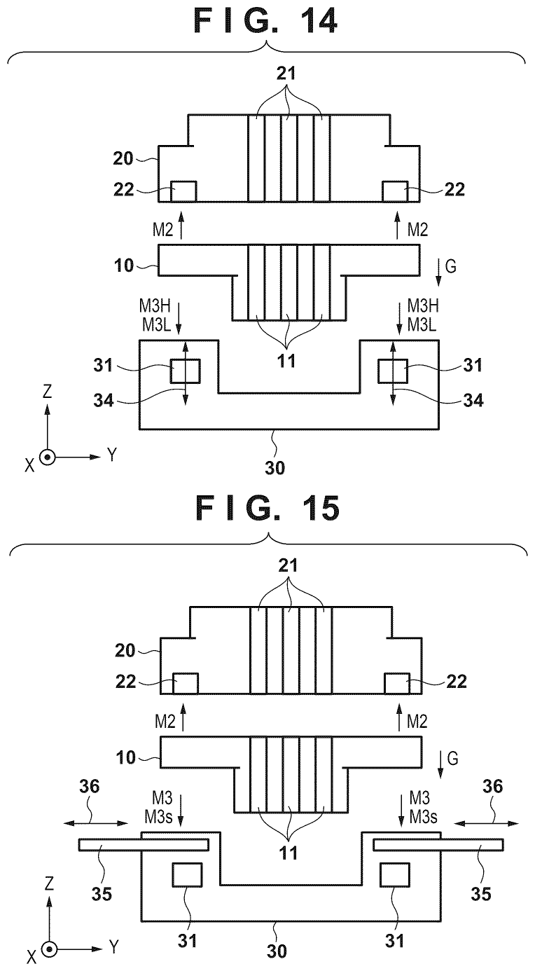

FIG. 14 shows Modification 1 of the second changer provided in the exchange holder 30. Here, an example will be described in which a first permanent magnet 22 is provided in a collet holder 20 and the second changer is provided in the exchange holder 30. Note that any of the arrangements described in the first embodiment may be applied to the arrangement of each of a collet 10 and the collet holder 20.

The second changer shown in FIG. 14 can include a second permanent magnet 31 that generates a magnetic force for attracting the collet 10, and a magnet driver 34 that drives the second permanent magnet 31 in the Z direction to move the second permanent magnet 31 closer to and away from the collet 10. In this arrangement, a controller CNT can change the second attraction force acting between the collet 10 and the exchange holder 30 by driving the second permanent magnet 31 in the Z direction by the magnet driver 34.

In Modification 1, the collet 10 includes a magnetic material, and self-weight compensation of the collet 10 is performed by the first permanent magnet 22 in the collet holder 20. The first permanent magnet 22 in the collet holder 20 also allows the collet holder 20 to hold the collet 10. The exchange holder 30 holds the collet 10 by the second permanent magnet 31. In the attachment process, the magnet driver 34 drives the second permanent magnet 31 to move the second permanent magnet 31 away from the collet 10, thereby decreasing the second attraction force acting between the collet 10 and the exchange holder 30. On the other hand, in the detachment process, the magnet driver 34 drives the second permanent magnet 31 to move the second permanent magnet 31 closer to the collet 10, thereby increasing the second attraction force acting between the collet 10 and the exchange holder 30.

Next, the relationship of forces acting on the collet 10 will be described. For example, as shown in FIG. 14, let “G” be the self-weight of the collet 10, and “M2” be the suction force generated by the first permanent magnet 22 in the collet holder 20. Further, let “M3H” be the suction force of the second permanent magnet 31 generated when the second permanent magnet 31 in the exchange holder 30 is moved closer to the collet 10, and “M3L” be the suction force of the second permanent magnet 31 generated when the second permanent magnet 31 in the exchange holder 30 is moved away from the collet 10. In this case, the respective forces need to satisfy the following relational expressions.

$$G < M 2 , M 2 < G + M 3 H , G + M 3 L < M 2$$

Next, the attachment process will be described. The attachment process is started in a state in which the collet 10 is held by the exchange holder 30. After the collet holder 20 and the exchange holder 30 are aligned, the collet holder 20 is lowered. Then, when the collet holder 20 contacts the collet 10 held by the exchange holder 30, the magnet driver 34 moves the second permanent magnet 31 away from the collet 10 to generate the suction force M3L by the second permanent magnet 31. In this case, the magnet driver 34 preferably sets the second permanent magnet 31 close to the collet 10 to keep generating the suction force M3H by the second permanent magnet 31 until the collet holder 20 completely contacts the collet 10.

When the magnet driver 34 moves the second permanent magnet 31 away from the collet 10, the second suction force acting between the collet 10 and the exchange holder 30 corresponds to the sum of the suction force M3L of the second permanent magnet 31 and the self-weight G of the collet 10 (G+M3L). On the other hand, the first attraction force acting between the collet 10 and the collet holder 20 is only the suction force M2 of the first permanent magnet 22. As a result, the balance between the first attraction force and the second attraction force is expressed as (G+M3L<M2). That is, the suction force of the second permanent magnet 31 is controlled by the magnet driver 34 so as to satisfy the above-described relational expression (G+M3L<M2), that is, so as to set the first attraction force larger than the second attraction force. When the collet holder 20 is lifted in this state, the collet 10 is attached to the collet holder 20.

Next, the detachment process will be described. The detachment process is started in a state in which the collet 10 is held by the collet holder 20. After the collet holder 20 and the exchange holder 30 are aligned, the collet holder 20 is lowered. Then, when the collet 10 held by the collet holder 20 contacts the exchange holder 30, the magnet driver 34 moves the second permanent magnet 31 closer to the collet 10 to generate the suction force M3H by the second permanent magnet 31. In this case, the magnet driver 34 preferably sets the second permanent magnet 31 away from the collet 10 by a certain amount until the collet 10 completely contacts the exchange holder 30.

When the magnet driver 34 moves the second permanent magnet 31 closer to the collet 10, the second suction force acting between the collet 10 and the exchange holder 30 corresponds to the sum of the suction force M3H of the second permanent magnet 31 and the self-weight G of the collet 10 (G+M3H). On the other hand, the first attraction force acting between the collet 10 and the collet holder 20 is only the suction force M2 of the first permanent magnet 22. As a result, the balance between the first attraction force and the second attraction force is expressed as (M2<G+M3H). That is, the suction force of the second permanent magnet 31 is controlled by the magnet driver 34 so as to satisfy the above-described relational expression (M2<G+M3H), that is, so as to set the second attraction force larger than the first attraction force. When the collet holder 20 is lifted in this state, the collet 10 is detached from the collet holder 20 and held by the exchange holder 30.

In this manner, in Modification 1, the attachment process and the detachment process are performed by controlling the suction force of the second permanent magnet 31 by driving the second permanent magnet 31 by the magnet driver 34. Here, in Modification 1, the second changer in the exchange holder 30 includes the second permanent magnet 31 and the magnet driver 34, but the first changer in the collet holder 20 can have a similar arrangement. That is, the first changer in the collet holder 20 may include the first permanent magnet and a magnet driver.

### [Modification 2]

FIG. 15 shows Modification 2 of the second changer provided in the exchange holder 30. Here, an example will be described in which the first permanent magnet 22 is provided in the collet holder 20 and the second changer is provided in the exchange holder 30. Note that any of the arrangements described in the first embodiment may be applied to the arrangement of each of the collet 10 and the collet holder 20.

The second changer shown in FIG. 15 can include the second permanent magnet 31 that generates a magnetic force for attracting the collet 10, a blocking member 35 that blocks a magnetic force, and a member driver 36 that drives the blocking member 35 so as to insert and remove the blocking member 35 between the second permanent magnet 31 and the collet 10. In this arrangement, the controller CNT can change the second attraction force acting between the collet 10 and the exchange holder 30 by driving the blocking member 35 by the member driver 36.

In Modification 2, the collet 10 includes a magnetic material, and self-weight compensation of the collet 10 is performed by the first permanent magnet 22 in the collet holder 20. The first permanent magnet 22 in the collet holder 20 also allows the collet holder 20 to hold the collet 10. The exchange holder 30 holds the collet 10 by the second permanent magnet 31. In the attachment process, the member driver 36 drives the blocking member 35 so as to insert the blocking member 35 between the second permanent magnet 31 and the collet 10, thereby decreasing the second attraction force acting between the collet 10 and the exchange holder 30. On the other hand, in the detachment process, the member driver 36 drives the blocking member 35 so as to remove the blocking member 35 between the second permanent magnet 31 and the collet 10, thereby increasing the second attraction force acting between the collet 10 and the exchange holder 30.

Next, the relationship of forces acting on the collet 10 will be described. For example, as shown in FIG. 15, let “G” be the self-weight of the collet 10, and “M2” be the suction force generated by the first permanent magnet 22 in the collet holder 20. Further, let “M3” be the suction force of the second permanent magnet 31 in a normal state in which the blocking member 35 is removed between the second permanent magnet 31 in the exchange holder 30 and the collet 10. Let “M3s” be the suction force of the second permanent magnet 31 in a state in which the blocking member 35 is inserted between the second permanent magnet 31 in the exchange holder 30 and the collet 10. In this case, the respective forces need to satisfy the following relational expressions. Note that the suction force M3s need not be zero, and may be weakened to a magnetic force at which the following relational expressions hold.

$$G < M 2 , M 2 < G + M 3 , G + M 3 s < M 2$$

Next, the attachment process will be described. The attachment process is started in a state in which the collet 10 is held by the exchange holder 30. After the collet holder 20 and the exchange holder 30 are aligned, the collet holder 20 is lowered. Then, when the collet holder 20 contacts the collet 10 held by the exchange holder 30, the member driver 36 inserts the blocking member 35 between the second permanent magnet 31 and the collet 10. In this case, the blocking member 35 is preferably kept removed between the second permanent magnet 31 and the collet 10 until the collet holder 20 completely contacts the collet 10.

When the member driver 36 inserts the blocking member 35 between the second permanent magnet 31 and the collet 10, the second suction force acting between the collet 10 and the exchange holder 30 corresponds to the sum of the suction force M3s of the second permanent magnet 31 and the self-weight G of the collet 10 (G+M3s). On the other hand, the first attraction force acting between the collet 10 and the collet holder 20 is only the suction force M2 of the first permanent magnet 22. As a result, the balance between the first attraction force and the second attraction force is expressed as (G+M3s<M2). That is, the suction force of the second permanent magnet 31 is controlled by the member driver 36 so as to satisfy the above-described relational expression (G+M3s<M2), that is, so as to set the first attraction force larger than the second attraction force. When the collet holder 20 is lifted in this state, the collet 10 is attached to the collet holder 20.

Next, the detachment process will be described. The detachment process is started in a state in which the collet 10 is held by the collet holder 20. After the collet holder 20 and the exchange holder 30 are aligned, the collet holder 20 is lowered. Then, when the collet 10 held by the collet holder 20 contacts the exchange holder 30, the member driver 36 removes the blocking member 35 between the second permanent magnet 31 and the collet 10. In this case, the blocking member 35 is preferably kept inserted between the second permanent magnet 31 and the collet 10 until the collet 10 completely contacts the exchange holder 30.

When the member driver 36 removes the blocking member 35 between the second permanent magnet 31 and the collet 10, the second suction force acting between the collet 10 and the exchange holder 30 corresponds to the sum of the suction force M3 of the second permanent magnet 31 and the self-weight G of the collet 10 (G+M3). On the other hand, the first attraction force acting between the collet 10 and the collet holder 20 is only the suction force M2 of the first permanent magnet 22. As a result, the balance between the first attraction force and the second attraction force is expressed as (M2<G+M3). That is, the suction force of the second permanent magnet 31 is controlled by the member driver 36 so as to satisfy the above-described relational expression (M2<G+M3), that is, so as to set the second attraction force larger than the first attraction force. When the collet holder 20 is lifted in this state, the collet 10 is detached from the collet holder 20 and held by the exchange holder 30.

In this manner, in Modification 2, the attachment process and the detachment process are performed by controlling the suction force of the second permanent magnet 31 by inserting and removing the blocking member 35 between the second permanent magnet 31 and the collet 10 by the member driver 36. Here, in Modification 2, the second changer in the exchange holder 30 includes the second permanent magnet 31, the blocking member 35, and the member driver 36, but the first changer in the collet holder 20 can have a similar arrangement. That is, the first changer in the collet holder 20 may include the first permanent magnet, a blocking member, and a member driver.

### Embodiment of Article Manufacturing Method

A method of manufacturing an article (a semiconductor IC element, a liquid crystal element, a MEMS, or the like) using the above-described bonding apparatus will be described. The article manufacturing method according to the embodiment of the present invention is suitable for, for example, manufacturing an article such as a microdevice (for example, a semiconductor device) or an element having a microstructure. The article manufacturing method according to the embodiment includes a bonding step of bonding a first member to a second member by using the above-described bonding apparatus, a processing step of processing the second member to which the first member has been bonded by the bonding step, and a manufacturing step of manufacturing an article from the second member processed in the processing step. The manufacturing method also includes other known processes (for example, probing, dicing, bonding, and packaging). The article manufacturing method according to the embodiment is superior to a conventional method in at least one of the performance, quality, productivity, and production cost of an article.

### OTHER EMBODIMENTS

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-221462 filed on Dec. 27, 2023, which is hereby incorporated by reference herein in its entirety.

What is claimed is:

1. A bonding apparatus that performs a process of bonding a first member to a second member, comprising:
a first holder configured to hold a chuck to be brought into contact with the first member in the process;
a second holder configured to hold the chuck in attachment of the chuck to the first holder and/or detachment of the chuck from the first holder;
a first attraction force generating mechanism configured to generate a first attraction force between the first holder and the chuck;
a second attraction force generating mechanism configured to generate a second attraction force between the second holder and the chuck; and
a controller configured to adjust at least one of the first attraction force and the second attraction force.

2. The apparatus according to claim 1, wherein the controller controls to set the first attraction force larger than the second attraction force in the attachment, and set the second attraction force larger than the first attraction force in the detachment.

3. The apparatus according to claim 1, wherein a first permanent magnet configured to generate a force of making the chuck and the first holder attract each other is provided as the first attraction force generating mechanism in at least one of the first holder and the chuck.

4. The apparatus according to claim 1, wherein the controller adjusts the first attraction force so as to change the first attraction force, and controls the second attraction force so as not to change the second attraction force.

5. The apparatus according to claim 1, wherein
the first holder includes, as the first attraction force generating mechanism, a first negative pressure generator configured to generate a negative pressure that draws the chuck, and
the controller adjusts the first attraction force by adjusting a negative pressure generated by the first negative pressure generator.

6. The apparatus according to claim 1, wherein
the first holder includes, as the first attraction force generating mechanism, a first electromagnet configured to generate a magnetic force that attracts the chuck, and
the controller adjusts the first attraction force by adjusting a magnetic force generated by the first electromagnet.

7. The apparatus according to claim 1, wherein a second permanent magnet configured to generate a force of making the chuck and the second holder attract each other is provided as the second attraction force generating mechanism in at least one of the second holder and the chuck.

8. The apparatus according to claim 1, wherein the controller controls the first attraction force so as not to change the first attraction force, and adjusts the second attraction force so as to change the second attraction force.

9. The apparatus according to claim 1, wherein
the second holder includes, as the second attraction force generating mechanism, a second negative pressure generator configured to generate a negative pressure that draws the chuck, and
the controller adjusts the second attraction force by adjusting a negative pressure generated by the second negative pressure generator.

10. The apparatus according to claim 1, wherein
the second holder includes, as the second attraction force generating mechanism, a second electromagnet configured to generate a magnetic force that attracts the chuck, and
the controller adjusts the second attraction force by adjusting a magnetic force generated by the second electromagnet.

11. The apparatus according to claim 1, wherein
the second holder includes
a second permanent magnet configured to generate a magnetic force for attracting the chuck, as the second attraction force generating mechanism, and
a magnet driver configured to drive the second permanent magnet to move the second permanent magnet closer to and away from the chuck, and
the controller adjusts the second attraction force by driving the second permanent magnet by the magnet driver.

12. The apparatus according to claim 1, wherein
the second holder includes
a second permanent magnet configured to generate a magnetic force for attracting the chuck, as the second attraction force generating mechanism,
a blocking member configured to block a magnetic force, and
a member driver configured to drive the blocking member to insert and remove the blocking member between the second permanent magnet and the chuck, and
the controller adjusts the second attraction force by driving the blocking member by the member driver.

13. The apparatus according to claim 1, further comprising a driving mechanism configured to relatively drive the first holder and the second holder,
wherein the controller controls the driving mechanism to align the first holder and the second holder in the attachment and/or the detachment.

14. The apparatus according to claim 1, wherein
the chuck has a contact surface that comes into contact with the first member, and
the second holder is configured to hold the chuck so as not to contact the contact surface of the chuck.

15. A chuck exchange apparatus comprising:
a second holder configured to hold a chuck in attachment of the chuck to a first holder configured to hold the chuck which is brought into contact with a first member in a process of bonding the first member to a second member, and/or detachment of the chuck from the first holder; and
a controller configured to control at least one of a first attraction force generating mechanism that generates a first attraction force between the first holder and the chuck, and a second attraction force generating mechanism that generates a second attraction force between the second holder and the chuck.

16. An article manufacturing method comprising:
bonding a first member to a second member by using a bonding apparatus defined in claim 1;
processing the second member to which the first member has been bonded by the bonding; and
manufacturing an article from the second member processed in the processing.
